(19) United States
(12) Patent Application Publication
(10) Pub. No.: US 2018/0151379 A1
(43) Pub. Date: May 31, 2018

(54) ELECTRODES FOR LOCALIZED CONTROL FACILITATING THE INTEGRATION OF POROUS SILICON FORMED BY GALVANIC ETCHING

(71) Applicant: THE UNITED STATES GOVERMENT AS REPRESENTED BY THE SECRETARY OF THE ARMY-U.S. ARMY RESEARCH LABORATOR, ADELPHI, MD (US)

(72) Inventors: MATTHEW HENDERSON ERVIN, CLARKSVILLE, MD (US); NICHOLAS WILLIAM PIEKIEL, WASHINGTON, DC (US); CHRISTOPHER JAMES MORRIS, SILVER SPRING, MD (US); WAYNE ANTHONY CHURAMAN, COLUMBIA, MD (US)

(73) Assignee: THE UNITED STATES GOVERNMENT AS REPRESENTED BY THE SECRETARY OF THE ARMY, WASHINGTON, DC (US)

(21) Appl. No.: 15/362,996

(22) Filed: Nov. 29, 2016

(51) Int. Cl. H01L 21/3063; H01L 21/308; H01L 21/283; H01L 21/3213; H01L 29/45; H01L 29/30

(52) U.S. Cl. CPC H01L 21/3063; H01L 21/3081; H01L 21/283; H01L 29/30; H01L 21/32134; H01L 29/456; H01L 21/3086

(57) ABSTRACT

A method of manufacturing a porous silicon (PSi) includes providing a semiconductor wafer; depositing a mask layer on a first side of the semiconductor wafer; patterning the mask layer to expose portions of semiconductor material of the semiconductor wafer; depositing a metal layer onto the patterned mask layer on a second side of the semiconductor wafer; and etching the semiconductor wafer where exposed by patterned portions of any of the mask layer and the metal layer thereby creating PSi regions at a surface of the semiconductor wafer. The method may further include patterning the metal layer prior to etching to form at least one electrode. The etching may include etching the semiconductor wafer with HF, a solvent, and hydrogen peroxide. The metal layer may form a plurality of electrodes segmented from each other.

### GOVERNMENT INTEREST

The embodiments herein may be manufactured, used, and/or licensed by or for the United States Government without the payment of royalties thereon.

### BACKGROUND

### Technical Field

The embodiments herein generally relate to porous silicon (PSi) devices, and more particularly to etching techniques of PSi devices.

### Description of the Related Art

Conventional PSi formation techniques describe processes to etch PSi using an anodic or galvanic process by depositing a noble metal electrode such as platinum (Pt) on one side of a silicon wafer, optionally masking the opposite side with a silicon nitride mask, and immersing the wafer in a solution containing hydrofluoric (HF) acid and hydrogen peroxide (H₂O₂) to etch PSi into the wafer side opposite the Pt electrode. These etch solutions also typically include an alcohol such as ethanol. The silicon area which is etched to produce PSi acts as the other electrode in this electrochemical etch process. Other conventional techniques disclose using the etching methods to fabricate combustible PSi channels with integrated electrical wires. These wires are used for both ignition and optionally, reaction propagation measurement. The conventional PSi formation processes generally only include an electrode on the opposite side of a wafer from the silicon to be etched, with only the silicon electrode having any pattern or design applied thereto. Since the conventional solutions use blanket metal electrodes on the backside of wafers to drive the etching of unpatterned or patterned features on the front side of the wafer, this arrangement typically results in uncontrolled variations in etch rate/depth across the wafer as a result of variations in exposed silicon.

### SUMMARY

In view of the foregoing, an embodiment herein provides a method of manufacturing a PSi device, the method comprising providing a silicon wafer comprising a first side and a second side; depositing an etchant resistant dielectric mask layer on the first side and the second side of the silicon wafer; depositing a metal layer on the first side of the silicon wafer; and etching silicon from the silicon wafer that is exposed by patterned regions in any of the etchant resistant dielectric mask layer and the metal layer thereby creating PSi regions at a surface of the silicon wafer. The method may further comprise removing the etchant resistant dielectric mask layer from the first side of the silicon wafer prior to depositing the metal layer. The method may further comprise patterning the etchant resistant dielectric mask layer on the first side of the silicon wafer to expose portions of the silicon wafer prior to depositing the metal layer, wherein the metal layer is deposited onto the patterned etchant resistant dielectric mask layer. The method may further comprise patterning the metal layer to expose portions of the silicon wafer prior to etching. The etching may comprise etching the silicon wafer with HF, a solvent, and hydrogen peroxide. The metal layer forms an electrode. The metal layer may form a plurality of electrodes segmented from each other. The edges of the metal layer may be protected from exposure to an etchant solution. The metal layer may be electrically connected to the silicon wafer.

Another embodiment provides a method of manufacturing a PSi device, the method comprising providing a silicon wafer; depositing a metal layer directly onto the silicon wafer; patterning the metal layer to expose portions of the silicon wafer; and etching the silicon wafer where exposed by patterned portions of the metal layer thereby creating PSi regions at a surface of the silicon wafer. The etching may comprise etching the silicon wafer with HF, a solvent, and hydrogen peroxide. The metal layer may form an electrode. The metal layer may form a plurality of electrodes segmented from each other. The edges of the metal layer which are exposed to an etchant solution may be electrically isolated from the silicon wafer. The edges of the metal layer may be protected from exposure to an etchant solution.

Another embodiment provides a method of manufacturing a porous semiconductor device, the method comprising providing a semiconductor wafer; depositing a mask layer on a first side of the semiconductor wafer; patterning the mask layer to expose portions of semiconductor material of the semiconductor wafer; depositing a metal layer onto the patterned mask layer on a second side of the semiconductor wafer; and etching the semiconductor wafer where exposed by patterned portions of any of the mask layer and the metal layer thereby creating porous semiconductor regions at a surface of the semiconductor wafer. The method may further comprise patterning the metal layer prior to etching to form at least one electrode. The etching may comprise etching the semiconductor wafer with HF, a solvent, and hydrogen peroxide. The metal layer may form a plurality of electrodes segmented from each other. The semiconductor in the semiconductor device, semiconductor wafer, and semiconductor material may comprise silicon (Si).

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1 is a cross-sectional drawing of the sacrificial electrode structure and etch process depicting the PSi etch undercutting the Pt electrode according to the embodiments herein;

FIG. 2 is a scanning electron microscope (SEM) cross-sectional image showing PSi etching underneath the Si₃N₄ defining the Si exposed to the PSi etch according to the embodiments herein;

FIG. 3 is a SEM cross-sectional image showing a Pt electrode peeling back from the PSi etch-front resulting in greater lateral etching under the Pt than the vertical etching into the Si surface according to the embodiments herein;

FIG. 4 is a SEM cross-sectional image showing undercutting of the Pt electrodes by electropolishing that is significantly more than the etch depth of the PSi in the exposed Si according to the embodiments herein;

FIG. 5 is a SEM cross-sectional image showing that undercutting of the Pt electrodes by electropolishing can leave a curved surface on the underlying Si/PSi according to the embodiments herein;

FIG. 6 is a SEM cross-sectional image showing the inhomogeneous PSi thickness that has been achieved using the sacrificial Pt approach according to the embodiments herein;

FIG. 7 is a cross-sectional drawing of the anchored electrode structure and etch process depicting the PSi etch undercutting the Si₃N₄ according to the embodiments herein;

FIG. 8 is a SEM cross-sectional image showing signs of electropolishing early in the etch when there is a small area of Si being etched, while better PSi is formed as the etch-front reaches deeper in the Si when there is a larger area of Si being etched according to the embodiments herein;

FIG. 9 is a SEM image showing cracked PSi circles formed closer to the Pt electrode and more uniform PSi circles etched farther from the Pt electrode according to the embodiments herein;

FIG. 10 is a cross-sectional drawing of an electrode structure and etch process depicting backside processing according to the embodiments herein;

FIG. 11 is a cross-sectional drawing of a segmented electrode structure and etch process depicting backside processing according to the embodiments herein;

FIG. 12 is a cross-sectional drawing of a segmented electrode structure and etch process depicting frontside processing according to the embodiments herein; and

FIG. 13 is a flow diagram illustrating a method according to an embodiment herein.

### DETAILED DESCRIPTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

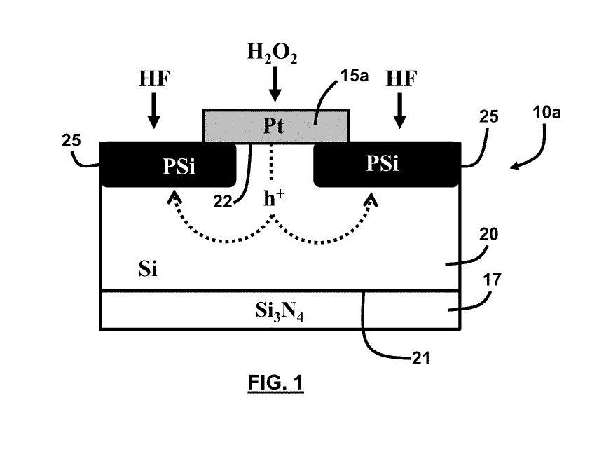

The embodiments herein provide a technique for etching PSi, which allows PSi devices to be more easily integrated with other devices used for initiating, controlling, or utilizing the output of the PSi devices. Referring now to the drawings, and more particularly to FIGS. 1 through 13, where similar reference characters denote corresponding features consistently throughout the figures, there are shown preferred embodiments.

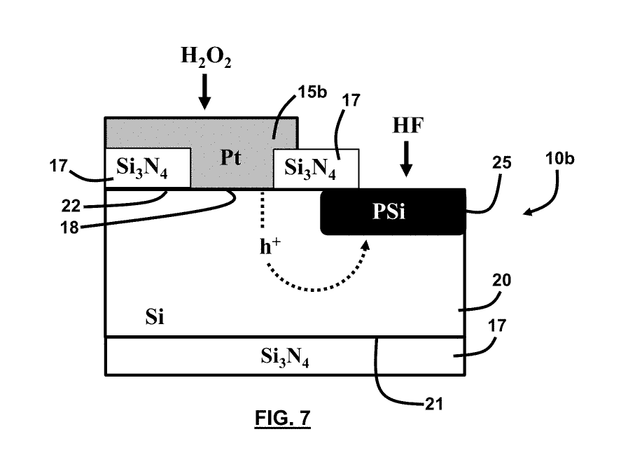

The embodiments herein provide multiple approaches for using patterned same-side or backside Pt electrodes to create PSi devices 10a, 10b. In a first approach shown in FIG. 1, in order to create the PSi device 10a, Pt electrodes 15a are deposited directly on the top (front) side 22 of a Si wafer 20 to be etched creating PSi regions 25. As described herein, the top (front) side 22 of the wafer 20 is the side of the wafer 20 on which the PSi will be etched. This approach is termed the sacrificial Pt electrode approach since it is expected that the PSi etch will etch the silicon of the Si wafer 20 underneath the Pt electrodes 15a, eventually releasing the Pt 15a from the wafer 20. In a second approach shown in FIG. 7, termed the anchored Pt electrode approach, in order to create the PSi device 10b, the Pt electrodes 15b are deposited onto the top side 22 of a Si wafer 20 that is covered with an etchant resistant material such as a patterned silicon nitride (Si₃N₄) layer 17. This dielectric Si₃N₄ layer 17 has openings 18 in it to expose the Si 20 to the PSi etch, and to make electrical contact between the Si 20 and the Pt electrodes 15b deposited on top of the Si₃N₄ 17.

By placing patterned electrodes 15a, 15b on the same-side (e.g., top/front side) 22 of the wafer 20 as the silicon to be etched, devices (not shown) on the other side 21 of the wafer 20 or elsewhere on the wafer surface may be protected from the highly corrosive concentrated hydrofluoric acid, ethanol, peroxide etch solution. These other devices (not shown) may be protected with a temporary or permanent coating of silicone or other etchant resistant material 17 or through the use of a vessel that limits the etchant contact with the wafer to a localized area(s) or wafer side.

In an exemplary embodiment, 1-10Ω p+Si wafers 20 are used as they produce nanoporous Si, which is desired for energetic PSi applications. These wafers 20 have on the order of 500 nm of Si₃N₄ 17 on both sides 21, 22. In the case of the sacrificial Pt electrodes 15a, the Si₃N₄ 17 is entirely removed from one side 22 of the wafer 20 while, in the case of anchored Pt electrodes 15b, photolithographically defined windows 18 are etched in the Si₃N₄ 17 to expose areas of top (front) side 22 of the Si wafer 20 for etching and for electrical contact to the Pt 15b. These nitride etches may be carried out using a reactive ion etch (RIE) system (not shown).

Once the Si₃N₄ 17 has been removed as desired, the Pt 15a, 15b is sputter deposited onto the wafer 20. First, the wafer 20 is etched for two minutes buffered hydrofluoric acid (BHF) solution to remove any oxide that may have formed since the nitride etch. Then, the wafer 20 is sputter cleaned for 30 sec in a sputter deposition system (not shown). Without breaking vacuum, the wafers 20 are then transferred to a Pt sputter chamber (not shown) where 170 nm of Pt 15a, 15b is sputter deposited at a sample temperature of 250° C. Alternatively, in other embodiments, evaporated Pt may be used, or atomic layer deposition may be used to deposit the Pt layer 15a, 15b, as well as other types of deposition techniques, and the embodiments herein are not restricted to a particular technique. This Pt layer 15a, 15b is patterned using photolithography and an ion mill or other suitable etch system (not shown), or it is deposited using a shadow mask or lift-off process.

The resulting wafers 20 that have patterned Pt electrodes 15a, 15b and exposed Si 20 are then etched with a HF, ethanol, and peroxide mixture. The ethanol reduces the viscosity/surface tension of the etch solution so that it can penetrate into the small pores being formed. A typical etch composition is 3:1 HF:ethanol with 2.4% peroxide added; however, many variations in concentrations and etch times can be used in accordance with the embodiments herein. As an alternative to ethanol, other suitable alcohols and solvents may be used in accordance with the embodiments herein.

Sacrificial Pt Electrodes

The sacrificial Pt approach utilizes only a Pt deposition and patterning process before the PSi etch. FIG. 1 illustrates a sample structure 10 and associated etch process. With a typical sacrificial Pt electrode 15a the sacrificial Pt electrode 15a is patterned to define the desired PSi etch area. There is expected lateral PSi etching underneath the sacrificial Pt electrode, with reference to FIG. 1.

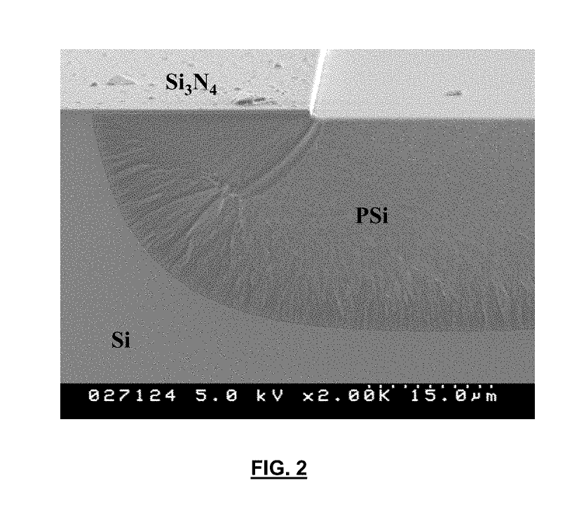

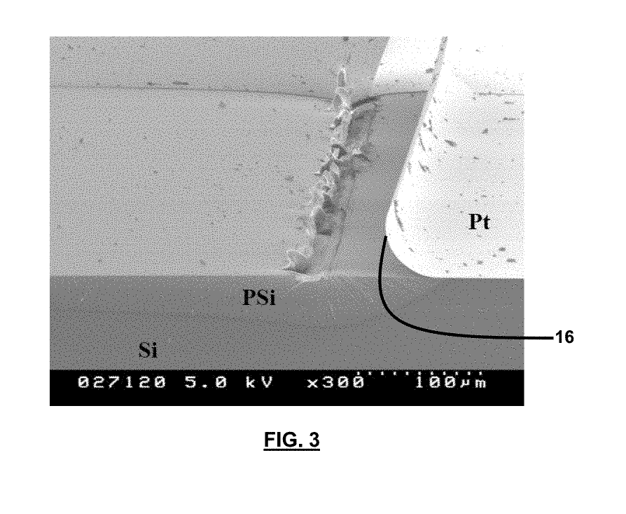

Given the expected isotropic PSi etching that undercuts the edges of the sacrificial Pt electrodes, topside sacrificial Pt electrodes 15a are designed to be at least as wide as the desired etch depth. In this way, the Pt 15a does not completely undercut until the desired etch depth is achieved. In addition, by varying the width ratio of the Pt electrodes 15a and the exposed Si 20, the etch current density and therefore etch rate can be controllable. In some circumstances, the PSi etching under the Pt edges 16 can enable the Pt 15a to detach and peel back from the surface of the Si 20. As a result, the Pt 15a can retreat from the etch-front producing greater lateral etching than the vertical etch depth as shown in FIG. 3, with reference to FIGS. 1 and 2.

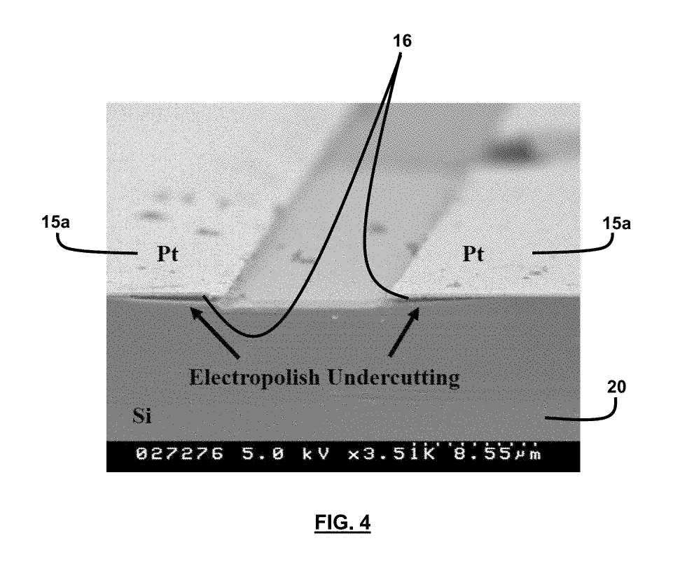

This enhanced lateral etching under the Pt 15a can be made even worse due to current crowding at the edges of the Pt electrodes as further described in Murrmann, H. et al., “Current crowding on metal contacts to planar devices,” IEEE Trans. On Electron Dev. 1969; 16(12), pp. 1022-1024, the complete disclosure of which, in its entirety, is herein incorporated by reference. The current crowding is due to the Pt electrode 15a being more conductive than the Si wafer 20 so that the path of least resistance for the carriers is to conduct through the Pt 15a and to transfer to the surface of the Si wafer primarily near the edge 16 of the Pt 15a in contact with the Si 20. There is then an enhanced etch rate near this Pt edge 16, since there is an additional resistance associated with conducting through the Si 20 to etch sites farther from the Pt 15a. This current crowding can increase the etch current density at the electrode edges into the electropolishing regime. An example of this is seen in the SEM cross-sectional image shown in FIG. 4, with reference to FIGS. 1 through 3, where the edges 16 of the Pt electrodes 15a can be seen to be undercut by about 8 microns while the PSi etch depth in the exposed Si area 20 is less than 1 micron.

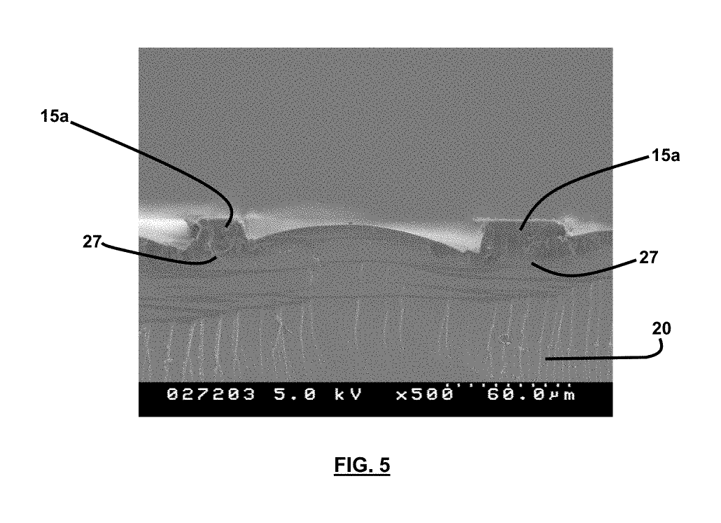

In many cases, the etch results in the Pt 15a being released from the surface of the Si 20 leaving behind a curved surface 27 in the area that was underneath the Pt 15a, as shown in FIG. 5, with reference to FIGS. 1 through 4. It appears that the electropolishing is greatest at the beginning of the etch. As more Pt 15a is undercut, there is more Si 20 exposed so that the Pt: Si ratio drops. This, in turn, reduces the etch current density and therefore reduces the electropolishing of the underlying Si 20.

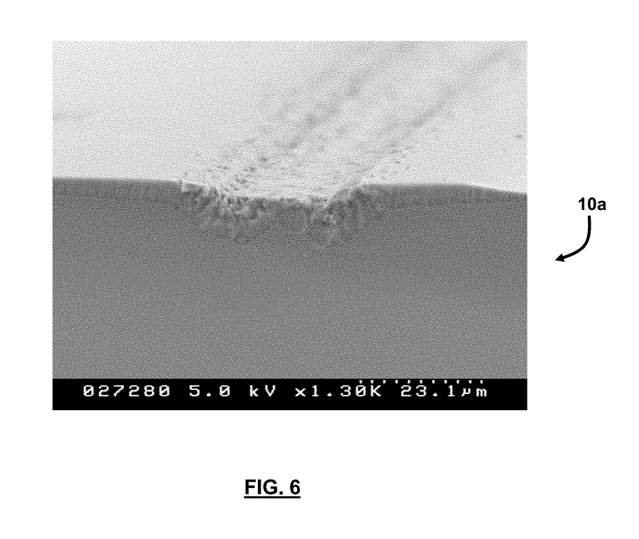

In order to minimize the deleterious electropolishing, the etch solution can be changed to minimize the etch current by reducing the H₂O₂ concentration or the H₂O₂ and HF concentrations. One approach can be to put the sample 10a into approximately 20 ml of ethanol and then adding approximately 1 ml of the normal etch solution every minute for approximately 30 min and then continuing the etch at that final 60% of normal concentration for another approximately 30 min. FIG. 6, with reference to FIGS. 1 through 5, shows the results of such an etch. The thickest PSi (9 microns) occurs in a narrow Si window with gradually thinning PSi underneath where the Pt was. This is the thickest PSi produced to this point with sacrificial Pt electrodes. Even if the Pt electrodes could be induced to stay adhered to the Si surface throughout the etch, it is possible that once PSi has etched completely underneath it, that the etch would then stop or greatly slow. This is because the Pt electrode contact resistance to the PSi should be significantly more resistive than it was to the unetched Si. In order to achieve thicker PSi films along with better control over the PSi pattern on the wafer, the anchored Pt approach can be used as described below.

Anchored Pt Electrodes

In the standard galvanic etch, the Pt electrode is deposited on the Si wafer backside and a patterned Si₃N₄ layer is used as a mask to define the PSi areas on the front side of the wafer. With the anchored Pt electrode approach shown in FIG. 7, the backside 21 of the Si wafer 20 is coated with Si₃N₄ 17 to prevent etching on the back of the wafer 20. The front (i.e., topside 22) of the wafer 20 still has a patterned Si₃N₄ or other HF resistant dielectric layer 17 exposing the Si 20 that is to be converted to PSi 25. In addition, the front side 22 also has openings 18 for Pt 15b deposited on top of the Si₃N₄ 17 to make electrical contact to the Si wafer 20. As depicted in FIG. 7, patterned Pt electrodes 15b are deposited on top of, and through holes 18 in, the Si₃N₄ layer 17, so that the Pt electrodes 15b have reliable adhesion throughout the PSi etch, and good electrical contact to the Si wafer 20.

The size and positions of the contact points to the Si 20 are not critical except insofar as the proximity effect discussed below may cause variations in the PSi etch depth and how they affect the overall resistance between the Pt electrodes and the Si to be etched as this will affect the etch rate and perhaps the properties of the resulting PSi. The Si₃N₄ 17 has resistance to the PSi etchant, which allows it to be used to define where the PSi 25 will be etched. In addition, the dielectric nature of the Si₃N₄ 17 prevents current crowding-increased etching or electropolishing at the edge of the Pt electrodes 15b. As long as the Pt contact points are sufficiently far from the exposed Si, the etch current sufficiently spreads out to reduce the likelihood of electropolishing at the near edge of the exposed Si 20.

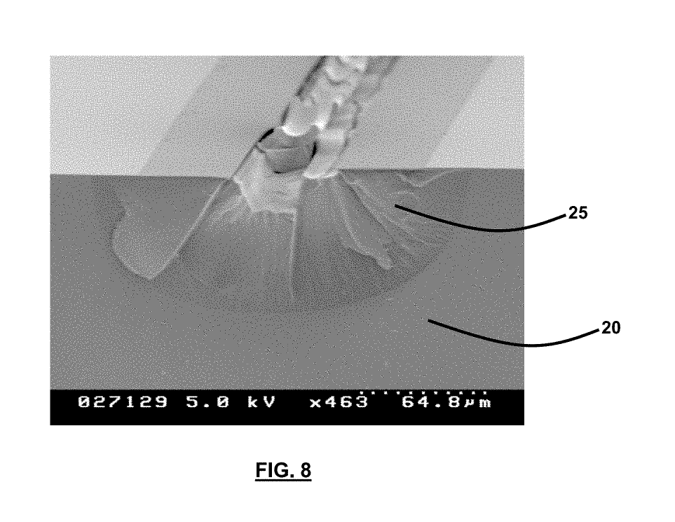

As was seen with the sacrificial electrodes 15a, electropolishing can occur if the H₂O₂ concentration is too high for the Pt: Si ratio being used. FIG. 8, with reference to FIG. 7, shows an example of a line of etched PSi 25 where the initial etching is near the electropolishing regime leading to broken and isolated pieces of PSi 25. As the etch progresses, the area of Si 20 at the etch-front increases so that the etch current density decreases moving it farther from the electropolishing regime so that better quality PSi is formed.

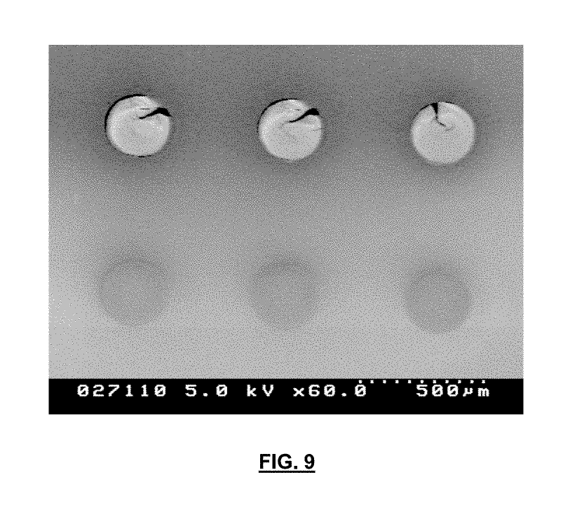

There can also be transitions from higher etch rates to lower etch rates as a function of distance from the Pt electrode 15b. This is essentially the same as the current crowding electropolishing seen at the edges 16 of Pt electrodes 15a with the sacrificial Pt etches described earlier. The only difference is that now, the Si₃N₄ mask layer 17 determines where the Si 20 is free to etch and depending on how far from the Pt electrode 15b it is, there is a proportional additional resistance due to conduction through the wafer 20. This proximity effect can result in features closer to the Pt 15b having different PSi etch rates and quality from features further from the Pt 15b as can be seen in FIG. 9, with reference to FIGS. 7 and 8.

There may also be proximity effects due to etch current depletion if there is etching of intervening PSi features between the more distant PSi features and the Pt electrode. Such proximity effects can be utilized by patterning electrodes 15a, 15b to intentionally produce local variation in etch currents in order to obtain increased uniformity or intentionally varied PSi properties across the wafer 20, which is not possible with the blanket electrodes used in the conventional techniques. In this regard, the same-side anchored electrodes 15b provide a means to locally control and vary PSi etching across a wafer 20 while protecting other devices that may be elsewhere on the wafer 20 or on the opposite side 21. The technique provided by the embodiments herein allows more uniform PSi performance or tailored PSi performance enabling different PSi functions on the same wafer with a single etching process. This feature is non-obvious in the industry based on the conventional solutions because the placement and pattern of such same-side electrodes requires an understanding of the internal electric fields established during the etch itself. These effects may be predicted to first order through modeling with resistor networks representing various resistors connecting each exposed silicon area and each same-side electrode. The sacrificial same-side electrodes 15a provided by the embodiments herein provide a unique solution as they conserve wafer area by not permanently committing surface area to etch electrodes 15a that have no function after the etch. This approach is useful when etch variations can be tolerated and when the area loading factor for PSi formation 25 is high.

Along with straight line PSi devices 10a, 10b, serpentine devices (not shown) with distances between lines down to 0.3 mm, including radii of curvatures down to 0.4 mm have been etched. In these devices, the Pt electrical contact points are 0.25 mm away from the edge of the Si₃N₄ defining the PSi line, and the Pt:Si ratio is 1.5:1 in the straight sections. In the curved sections, the Pt:Si ratio varies between 0.688:1 and 3.94:1 depending on whether the associated Pt electrode is inside or outside of the PSi curve, respectively. Even with this large local variation in the Pt:Si ratio in the curves, there is no trend in PSi etch depth with local Pt: Si ratio observed. This is because the holes generated at the Pt surface easily conduct along the length of the Pt electrode so that there are no locally increased etch current densities. In order to vary the PSi etch rate along the serpentine, isolated Pt electrodes with different local Pt: Si ratios would have to be placed along the serpentine. In general, the distance between adjacent PSi features is limited by the PSi etch depth as this affects the undercutting of the mask edges that will eventually cause distinct PSi regions to coalesce into one PSi feature.

Patterned Backside Electrodes

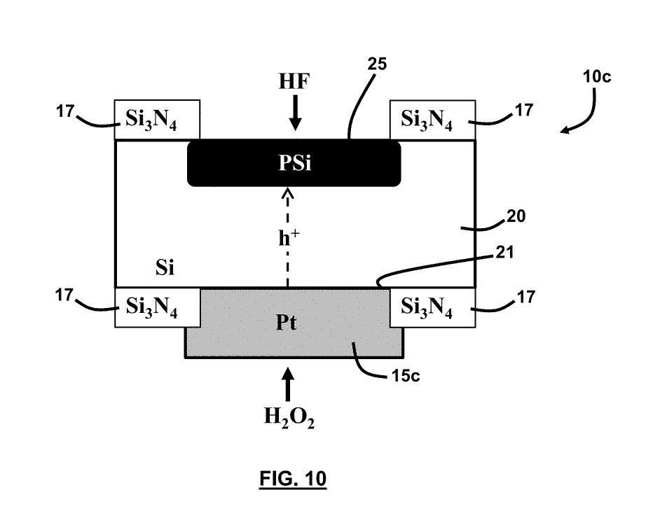

Additionally, as shown in FIG. 10, with reference to FIGS. 1 through 9, the embodiments herein provide a technique to create a PSi device 10c having wafer backside 21 patterned electrodes 15c, which controls the galvanic etching of patterned PSi features 25 so as to obtain increased uniformity or intentionally varied PSi properties across the wafer 20, which is not possible with the blanket electrodes used in the conventional techniques. By patterning the backside 21 Pt electrodes 15c in addition to the front side silicon electrodes 15a, 15b (of FIGS. 1 and 7, respectively), the embodiments herein allow patterned PSi features 25 to be made more uniformly, or in a more controlled fashion, than if a blanket backside Pt electrode were used. The patterned backside electrode aspect of the embodiments herein use patterned electrodes 15c as an etch current “knob” in PSi galvanic synthesis, which provides a more consistent etch current and thus a more uniform PSi film throughout a sample. For example, the use of patterned backside 21 electrodes 15c results in a 9% etch depth variation across a 7-fold variation in silicon electrode width, which is a 12-fold improvement over using the non-patterned Pt electrode in the conventional solutions. The use of patterned backside electrodes 15c can also enable intentional variations by pairing and aligning different sizes with appropriately patterned frontside 22 silicon electrodes 15a, 15b, resulting in more intentional variations in etch depth. Variations in etch depth can affect burn rates so that a slower section could be used for a delay line, and a faster burning section could be used to initiate a munitions explosive train.

The techniques provided by the embodiments herein allow for the control of the PSi etch across a wafer 20 resulting in features 25 with more uniform or intentionally varied PSi properties across the wafer 20 as desired, with a single etch process. The etch electrodes 15a, 15b can be patterned to vary the etch rate as there is a proximity effect whereby the etching of silicon features 25 are more effected by the electrodes 15a, 15b closer to the features 25. For instance, features 25 closer to the electrodes 15a, 15b etch faster.

Segmented Electrodes

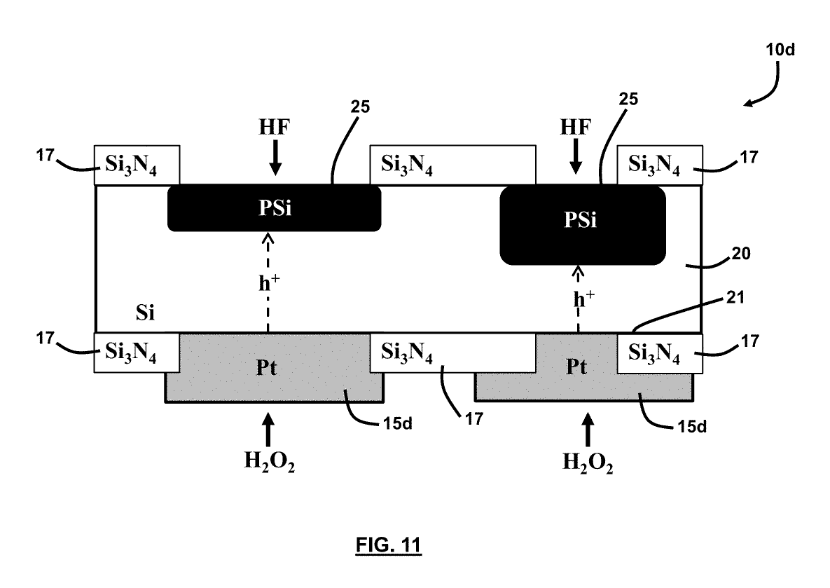

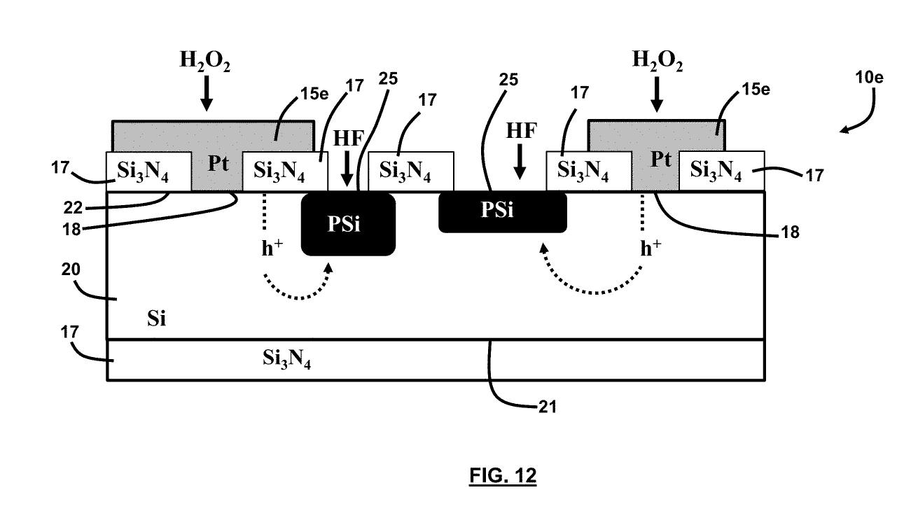

As shown in FIGS. 11 and 12, with reference to FIGS. 1 through 10, in order to vary the etch depth by varying the local electrode/silicon ratio or silicon-to-electrode distance, the patterned frontside 22 or backside 21 electrode 15d, 15e is cut up (i.e., segmented) into electrically isolated sections to prevent the etch current from conducting along the length of the electrode 15e, 15e, which would result in the current preferentially etching the most accessible exposed silicon 20. FIG. 11 shows a PSi device 10d comprising a segmented backside 22 electrode 15d, and FIG. 12 shows a PSi device 10e comprising a segmented frontside 21 electrode 15e. This electrical isolation between electrodes 15d, 15e must also take into account the resistance of the electrical paths between the Pt electrode segments 15d, 15e through the Si wafer 20. In other words, additional control is obtained by segmenting the electrodes 15d, 15e so that the individual electrodes 15d, 15e may be tailored to control the etch rate of nearby features 25 where they have more influence. Conversely, non-segmented continuous electrodes 15a, 15b, 15c conduct the electrochemical current along their length so that local variations in electrode-to-silicon ratios are ineffective at controlling local etch rates/depths.

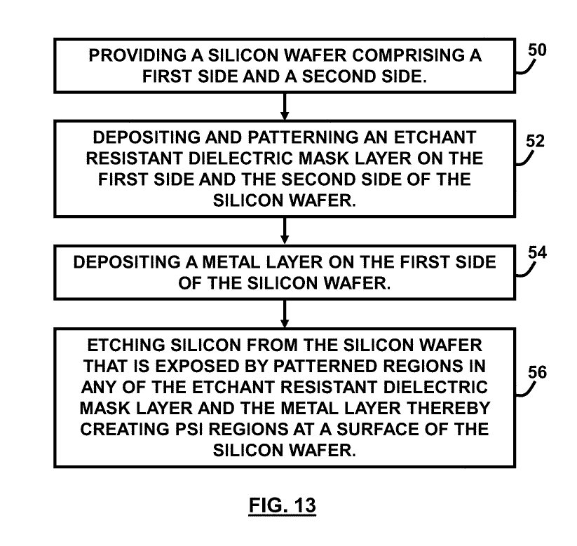

FIG. 13, with reference to FIGS. 1 through 12, is a flow diagram illustrating a method of manufacturing a PSi device 10a-10e, the method comprising providing (50) a semiconductor (e.g., silicon) wafer 20 comprising a first side (21 or 22) and a second side (22 or 21); depositing and patterning (52) an etchant resistant dielectric mask layer 17 on the first side (21 or 22) and the second side (22 or 21) of the silicon wafer 20; depositing (54) a metal layer 15a-15e on the first side (21 or 22) of the silicon wafer 20; and etching (56) silicon from the silicon wafer 20 that is exposed by patterned regions 18 in any of the etchant resistant dielectric mask layer 17 and the metal layer 15a-15e thereby creating PSi regions 25 at a surface of the silicon wafer 20. The method may further comprise removing the etchant resistant dielectric mask layer 17 from the first side (21 or 22) of the silicon wafer 20 prior to depositing the metal layer 15a-15e. The patterning (52) of the etchant resistant dielectric mask layer 17 may comprise patterning the etchant resistant dielectric mask layer 17 on the first side (21 or 22) of the silicon wafer 20 to expose portions of the silicon wafer 20 prior to depositing (54) the metal layer 15a-15e, wherein the metal layer 15a-15e is deposited onto the patterned etchant resistant dielectric mask layer 17. The method may further comprise patterning the metal layer 15a-15e to expose portions of the silicon wafer 20 prior to etching (56). The etching (56) may comprise etching the silicon wafer with HF, a solvent, and hydrogen peroxide. The metal layer 15a-15e forms an electrode. Additionally, the metal layer 15a-15e may form a plurality of electrodes 15d-15e segmented from each other. Edges 16 of the metal layer 15a-15e which are exposed to an etchant solution may be electrically isolated from the silicon wafer 20. The edges 16 may be isolated from the silicon wafer 20 or etch solution using the etchant resistant dielectric mask layer 17 under the edge 16 or by covering the metal layer edge/silicon wafer interface using a photoresist, for example. The edges 16 of the metal layer 15a-15e may be protected from exposure to the etchant solution. In one embodiment, the metal layer 15a-15e is electrically connected to the silicon wafer 20 at some point(s).

The embodiments herein may be used to enhance the fabrication of PSi 25 for many applications including, but not limited to: (1) Energetic PSi devices which are produced by depositing an oxidixer, such as sodium perchlorate, sulfur, etc., onto the PSi and including a means of igniting the device, such as an incorporated bridge wire. These devices, when ignited, could be used for the light, heat, sound, chemical reaction, gases, shock wave, or other outputs that result. In particular, they may be useful for microthruster, fuzing, high-explosive initiation, energy production and other energetic applications. (2) PSi is a desirable substrate upon which to build passive electrical components such as resistors, capacitors, inductors, and antennae. Because the performance of passive components is limited when fabricated in close proximity to lossy silicon substrates and other metallization, PSi offers a unique solution as an isolation layer. The embodiments herein allow greater flexibility in the integration of PSi with microfabricated or other existing components on a silicon substrate. (3) Other applications include drug delivery, where PSi can be used to deliver therapeutics to directed areas within the human body, or biosensors to detect various analytes such as glucose, DNA, antibodies, bacteria, and viruses. These sensors also require electrical contacts, passive components, and active (i.e., electronic logic components). (4) PSi can be used in the development of micro-fuel cells because of its ability to provide an effective gas diffusion layer, catalyst support, and membrane structure. Such cells imply the incorporation of other electrodes in order to extract desired electrical power. (5) The surface of PSi can be modified to incorporate quantum confinement and accommodate dangling bonds, and can produce red, blue, and infrared photoluminescence bands. These phenomena can result in light emitting devices based on PSi. More effective waveguides incorporating PSi films can also be produced with etching processes tailored to produce PSi with the correct refractive index for the desired waveguide. (6) Sacrificial same-side electrodes enable the use of a simpler process to obtain some of the same attributes of the same-side anchored electrodes. However, the PSi etch depth is limited because the sacrificial electrodes come off the sample relatively quickly due to enhanced etching at the contact point between the electrode and the silicon. This approach allows PSi to be etched on the surface without permanently dedicating surface area to electrodes that have no use after the etch. Another application is in solar cells where the PSi enhances the absorption of light, but additional light absorbing area is not sacrificed to provide etch electrodes after the etch has terminated.

The embodiments described herein are described as galvanic PSi etch processes, however, analogous anodic etch processes may be described by replacing the H₂O₂ in the etch solution with an external source of current provided by a power supply attached to the metal electrodes. In general, the catalytic action of the Pt electrodes on the H₂O₂ injects holes (electrical current) into the silicon wafer which could alternatively be provided by a power supply.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

What is claimed is:

1. A method of manufacturing a porous silicon (PSi) device, said method comprising:
providing a silicon wafer comprising a first side and a second side;
depositing an etchant resistant dielectric mask layer on said first side and said second side of said silicon wafer;
depositing a metal layer on said first side of said silicon wafer; and
etching silicon from said silicon wafer that is exposed by patterned regions in any of said etchant resistant dielectric mask layer and said metal layer thereby creating PSi regions at a surface of said silicon wafer.

2. The method of claim 1, further comprising removing said etchant resistant dielectric mask layer from said first side of said silicon wafer prior to depositing said metal layer.

3. The method of claim 1, further comprising patterning said etchant resistant dielectric mask layer on said first side of said silicon wafer to expose portions of said silicon wafer prior to depositing said metal layer, wherein said metal layer is deposited onto the patterned etchant resistant dielectric mask layer.

4. The method of claim 1, further comprising patterning said metal layer to expose portions of said silicon wafer prior to etching.

5. The method of claim 1, wherein said etching comprises etching said silicon wafer with hydrofluoric acid (HF), a solvent, and hydrogen peroxide.

6. The method of claim 1, wherein said metal layer forms an electrode.

7. The method of claim 1, wherein said metal layer forms a plurality of electrodes segmented from each other.

8. The method of claim 1, wherein edges of said metal layer which are exposed to an etchant solution are electrically isolated from said silicon wafer.

9. The method of claim 1, wherein edges of said metal layer are protected from exposure to an etchant solution.

10. The method of claim 1, wherein said metal layer is electrically connected to said silicon wafer.

11. A method of manufacturing a porous silicon (PSi) device, said method comprising:
providing a silicon wafer;
depositing a metal layer directly onto said silicon wafer;
patterning said metal layer to expose portions of said silicon wafer; and
etching said silicon wafer where exposed by patterned portions of said metal layer thereby creating PSi regions at a surface of said silicon wafer.

12. The method of claim 11, wherein said etching comprises etching said silicon wafer with hydrofluoric acid (HF), a solvent, and hydrogen peroxide.

13. The method of claim 11, wherein said metal layer forms an electrode.

14. The method of claim 11, wherein said metal layer forms a plurality of electrodes segmented from each other.

15. The method of claim 11, wherein edges of said metal layer are protected from exposure to an etchant solution.

16. A method of manufacturing a porous semiconductor device, said method comprising:
providing a semiconductor wafer;
depositing a mask layer on a first side of said semiconductor wafer;
patterning said mask layer to expose portions of semiconductor material of said semiconductor wafer;
depositing a metal layer onto the patterned mask layer on a second side of said semiconductor wafer; and
etching said semiconductor wafer where exposed by patterned portions of any of said mask layer and said metal layer thereby creating porous semiconductor regions at a surface of said semiconductor wafer.

17. The method of claim 16, further comprising patterning said metal layer prior to etching to form at least one electrode.

18. The method of claim 16, wherein said etching comprises etching said semiconductor wafer with hydrofluoric acid (HF), a solvent, and hydrogen peroxide.

19. The method of claim 16, wherein said metal layer forms a plurality of electrodes segmented from each other.

20. The method of claim 16, wherein the semiconductor in said semiconductor device, said semiconductor wafer, and said semiconductor material comprises silicon (Si).
